(19) United States
(12) Patent Application Publication
(10) Pub. No.: US 2012/0171500 A1
(43) Pub. Date: Jul. 5, 2012

(54) PROCESS FOR SURFACE TREATING MAGNESIUM ALLOY AND ARTICLE MADE WITH SAME

(75) Inventors: HSIN-PEI CHANG, Tu-Cheng (TW); WEN-RONG CHEN, Tu-Cheng (TW); HUANN-WU CHIANG, Tu-Cheng (TW); CHENG-SHI CHEN, Tu-Cheng (TW); DUN MAO, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/188,566

(22) Filed: Jul. 22, 2011

(30) Foreign Application Priority Data
Dec. 30, 2010 (CN) 201010614871.4

(51) Int. Cl. B32B 15/04; C23C 14/34; C23C 14/35

(52) U.S. Cl. 428/457; 204/192.12; 204/192.38

(57) ABSTRACT

A process for treating the surface of magnesium alloy comprises providing a substrate made of magnesium alloy. The substrate is then treated with a chemical conversion treatment solution containing oleic acid as a main film forming agent, to form an oleic acid conversion film on the substrate. A ceramic coating comprising refractory metal compound is next formed on the cerium conversion film by physical vapor deposition.

### CROSS-REFERENCE TO RELATED APPLICATIONS

This application is related to co-pending U.S. patent application Ser. Nos. (Attorney Docket No. US35144, US36043, and US36046, each entitled “PROCESS FOR SURFACE TREATING MAGNESIUM ALLOY AND ARTICLE MADE WITH SAME”, each invented by Chang et al. These applications have the same assignee as the present application. The above-identified applications are incorporated herein by reference.

### BACKGROUND

1. Technical Field

The disclosure generally relates to a process for surface treating magnesium alloy, and articles made of magnesium alloy treated by the process.

2. Description of Related Art

Magnesium alloys are widely used in manufacturing components (such as housings) of electronic devices and cars because of their properties such as light weight and quick heat dissipation. However, magnesium alloys have a relatively low erosion resistance and abrasion resistance. One method for enhancing the erosion resistance of magnesium alloy is to form ceramic coatings on its surface. However, cast magnesium alloy has many pinholes on its surface. The ceramic coatings over these pinholes are usually thinner and weaker than other portions having no pinhole, rendering pitting corrosion more likely at these locations.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the exemplary process for the surface treating of magnesium alloy and articles made of magnesium alloy treated by the process. Moreover, in the drawings, like reference numerals designate corresponding parts throughout the several views. Wherever possible, the same reference numbers are used throughout the drawings to refer to the same or like elements of an embodiment.

FIG. 1 is a cross-sectional view of an exemplary article treated in accordance with the present process.

FIG. 2 is a block diagram of a process for the surface treating of magnesium alloy according to an exemplary embodiment.

FIG. 3 is a schematic view of a vacuum sputtering machine for processing the exemplary article shown in FIG. 1.

### DETAILED DESCRIPTION

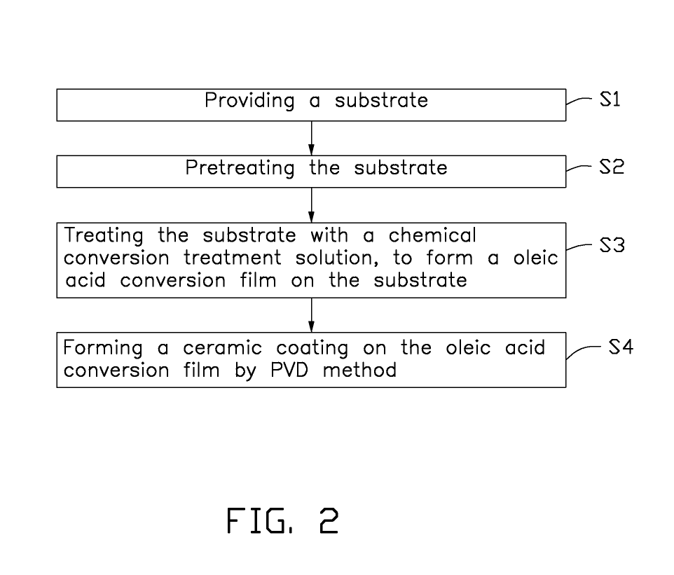

Referring to FIG. 2, an exemplary process for the surface treatment of magnesium alloy may include steps S1 to S4.

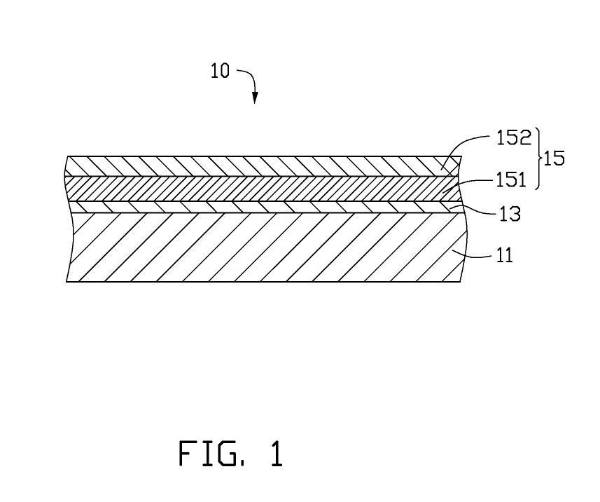

In step S1, referring to FIG. 1, a substrate 11 is provided. The substrate 11 is made of a magnesium alloy, such as Mg—Al alloy, or Mg—Al—Zn alloy.

In step S2, the substrate 11 is pretreated. The pretreatment may include the following steps.

Firstly, the substrate 11 is chemically degreased with an aqueous solution, to remove impurities such as grease or dirt from the substrate 11. The aqueous solution may contain about 25 g/L-30 g/L sodium carbonate (Na₂CO₃), about 20 g/L-25 g/L trisodium phosphate dodecahydrate (Na₃PO₄.12H₂O), and an emulsifier. The emulsifier may be a trade name emulsifier OP-10 (a condensation product of alkylphenol and ethylene oxide) at a concentration of about 1 g/L-3 g/L. The substrate 11 is immersed in the aqueous solution at a temperature of about 60° C.-80° C. for about 30 s-60 s. Then, the substrate 11 is rinsed for about 20 s-60 s.

Then, the degreased substrate 11 is etched in an alkaline etchant, to create a smooth surface and further remove any impurities thereon. The alkaline etchant is an aqueous solution containing about 40 g/L-70 g/L sodium hydroxide (NaOH), about 10 g/L-20 g/L Na₃PO₄.12H₂O, about 25 g/L-30 g/L Na₂CO₃, and about 40 g/L-50 g/L sodium fluoride (NaF). The substrate 11 is immersed in the alkaline etchant, which is maintained at a temperature of about 40° C.-50° C., for about 3 s-5 s. During this process, burrs and other small sized protrusions are dissolved.

The substrate 11 is then activated using an activating solution, to improve the bonding ability of the surface of the substrate 11 with the subsequent film. The activating solution is an aqueous solution containing hydrofluoric acid (HF) at a concentration of about 1%-3% by weight. The substrate 11 is immersed in the activating solution at room temperature for about 3 s-5 s, to remove any oxide film on the substrate 11.

In step S3, when the pretreatment is finished, the substrate 11 undergoes a chemical conversion treatment, to form an oleic acid conversion film 13. The chemical conversion treatment applies a chemical conversion treatment solution containing oleic acid (also named as cis-9-octadecenoic acid) as the main film forming agent. The chemical conversion treatment solution is an aqueous solution containing about 10 ml/L-30 ml/L oleic acid, and ketone compounds such as acetone for facilitating the dissolution of the oleic acid. The pH value of the chemical conversion treatment solution may be between about 2 and 5. The chemical conversion treatment may be carried out by immersing the substrate 11 in the chemical conversion treatment solution maintained at about 30° C.-50° C. for about 2 min to 4 min. During the immersion, the chemical conversion treatment solution may be stirred. In an exemplary embodiment, the chemical conversion treatment solution is an aqueous solution containing about 15 ml/L oleic acid and acetone, with a pH value of about 2.8. The substrate 11 is immersed in the chemical conversion treatment solution maintained at about 35° C. for about 2.5 min. By this process, anions in the chemical conversion treatment solution react with metal atoms on a surface layer of the substrate 11, thus an oleic acid conversion film 13 is formed on the substrate 11.

In step S4, a ceramic coating 15 is formed on the oleic acid conversion film 13 by physical vapor deposition, such as magnetron sputtering or arc ion plating. The ceramic coating 15 may be single layer or multilayer refractory metal compound. The refractory metal compound can be selected from one or more of the group consisting of nitride of titanium, aluminum, chromium, zirconium, or cobalt; carbonitride of titanium, aluminum, chromium, zirconium, or cobalt; and oxynitride of titanium, aluminum, chromium, zirconium, or cobalt. In this exemplary embodiment, the ceramic coating 15 includes a first layer 151 coated on the oleic acid conversion film 13 and a second layer 152 on the first layer 151. The first layer 151 is an aluminum-oxygen compound layer. The second layer 152 is a chromium-oxygen-nitrogen compound layer. An exemplary process for forming the ceramic coating 15 may be performed by the following steps.

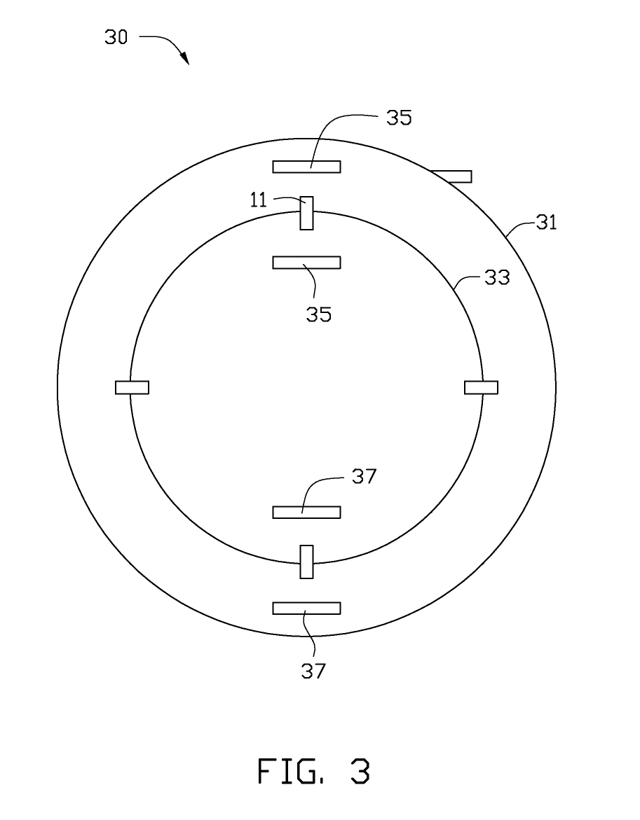

The first layer 151 is directly formed on the oleic acid conversion film 13 by vacuum sputtering. The substrate 11 is held on a rotating bracket 33 in a chamber 31 of a vacuum sputtering machine 30 as shown in FIG. 3. The chamber 31 is evacuated to maintain an internal pressure of about 6×10⁻³ Pa to 8×10⁻³ Pa and the inside of the chamber 31 is heated to a temperature of about 100° C. to about 150° C. The speed of the rotating bracket 33 is about 0.5 revolutions per minute (rpm) to about 1.0 rpm. Argon and oxygen are simultaneously fed into the chamber 31, with the argon acting as a sputtering gas, and the oxygen acting as a reactive gas. The flow rate of argon is about 150 standard-state cubic centimeters per minute (sccm) to about 300 sccm. The flow rate of oxygen is about 50 sccm to 90 sccm. A bias voltage of about −100 volts (V) to about −300 V is applied to the substrate 11. About 8 kW to about 10 kW of electric power is applied to aluminum targets 35 fixed in the chamber 31, depositing the first layer 151 on the oleic acid conversion film 13. Depositing the first layer 151 may take about 30 min to about 60 min The power may be medium-frequency AC power.

Subsequently, the second layer 152 is directly formed on the first layer 151 also by vacuum sputtering. This step may be carried out in the vacuum sputtering machine 30. The aluminum targets 35 are switched off. Argon, oxygen, and nitrogen are simultaneously fed into the chamber 31. The flow rate of oxygen is adjusted to about 40 sccm to about 100 sccm, and the flow rate of nitrogen is about 30 sccm to about 60 sccm. About 8 kW to about 10 kW of electric power is applied to chromium targets 37 fixed in the chamber 31, depositing the second layer 152 on the first layer 151. Depositing the second layer 152 may take about 30 min to about 120 min. Other parameters are the same as during deposition of the first layer 151.

The oleic acid conversion film 13 has a good chemical stability and high compact density, with a good erosion resistance. In addition, the oleic acid conversion film 13 provides a smooth surface on the substrate 11, and by such means the ceramic coating 15 formed on the oleic acid conversion film 13 has a substantially even thickness, reducing the susceptibility to pit corrosion. Composed of refractory metal compounds and having a high abrasion resistance, the ceramic coating 15 protects the oleic acid conversion film 13 from mechanical abrasion.

FIG. 1 shows a cross-section of an exemplary article 10 made of magnesium alloy and processed by the surface treatment process as described above. The article 10 may be a housing for an electronic device, such as a mobile phone. The article 10 includes the substrate 11 made of magnesium alloy, the oleic acid conversion film 13 formed on the substrate 11, and the ceramic coating 15 formed on the oleic acid conversion film 13.

The oleic acid conversion film 13 is formed by chemical conversion treatment using a chemical conversion treatment solution containing oleic acid as the main film forming agent, as described above. The ceramic coating 15 may be a single layer or multilayer refractory metal compound. The refractory metal compound can be selected from one or more of the group consisting of nitride of titanium, aluminum, chromium, zirconium, or cobalt; carbonitride of titanium, aluminum, chromium, zirconium, or cobalt; and oxynitride of titanium, aluminum, chromium, zirconium, or cobalt. In this exemplary embodiment, the ceramic coating 15 orderly includes a first layer 151 coated on the oleic acid conversion film 13, and a second layer 152 on the first layer 151. The first layer 151 is an aluminum-oxygen compound layer. The second layer 152 is a chromium-oxygen-nitrogen compound layer.

A neutral salt spray test was applied to the samples created by the present process. The test conditions included 5% NaCl (similar to salt-fog chloride levels), and the test was an accelerated corrosion test for assessing coating performance. Erosion began to be observed after about 72 hours, indicating that the samples resulting from the present process have a good erosion resistance.

It is to be understood, however, that even through numerous characteristics and advantages of the exemplary disclosure have been set forth in the foregoing description, together with details of the system and functions of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A process for surface treating magnesium alloy, the process comprising the following steps of:
providing a substrate made of magnesium alloy;
forming a oleic acid conversion film on the substrate by treating the substrate with a chemical conversion treatment solution containing oleic acid as a main film forming agent; and
forming a ceramic coating comprising refractory metal compound on the chemical conversion film by physical vapor deposition.

2. The process as claimed in claim 1, wherein the chemical conversion treatment solution is an aqueous solution containing about 10 ml/L-30 ml/L oleic acid, and ketone compounds, and having a pH value between about 2 and 5.

3. The process as claimed in claim 2, wherein treating the substrate with the chemical conversion treatment solution is carried out by immersing the substrate in the chemical conversion treatment solution, which is maintained at about 30° C.-50° C., for about 2 min to 4 min.

4. The process as claimed in claimed 2, wherein the chemical conversion treatment solution is an aqueous solution containing about 15 ml/L oleic acid, and acetone, and having a pH value of about 2.8.

5. The process as claimed in claimed 4, wherein the treating the substrate with the chemical conversion treatment solution is carried out by immersing the substrate in the chemical conversion treatment solution, which is maintained at about 35° C., for about 2.5 min.

6. The process as claimed in claimed 1, wherein the refractory metal compound is selected from one or more of the group consisting of nitride of titanium, aluminum, chromium, zirconium, or cobalt; carbonitride of titanium, aluminum, chromium, zirconium, or cobalt; and oxynitride of titanium, aluminum, chromium, zirconium, or cobalt.

7. The process as claimed in claimed 6, wherein the ceramic coating includes a first layer coated on the oleic acid conversion film and a second layer on the first layer, wherein, the first layer is an aluminum-oxygen compound layer, the second layer is a chromium-oxygen-nitrogen compound layer.

8. The process as claimed in claim 1, wherein the physical vapor deposition uses a vacuum sputtering method or an arc ion plating method.

9. The process as claimed in claim 1, further comprising a step of etching the substrate using an alkaline etchant containing about 40 g/L-70 g/L NaOH, about 10 g/L-20 g/L Na₃PO₄.12H₂O, about 25 g/L-30 g/L Na₂CO₃, and about 40 g/L-50 g/L NaF, before treating the substrate with the chemical conversion treatment solution.

10. The process as claimed in claim 9, wherein the etching step is carried out by immersing the substrate in the alkaline etchant maintained at a temperature of about 40° C.-50° C. for about 3 s-5 s.

11. The process as claimed in claim 9, further comprising chemically degreasing the substrate, before the etching step.

12. The process as claimed in claim 9, further comprising sactivating the substrate by immersing the substrate in an aqueous solution containing hydrofluoric acid at a concentration of about 1%-3% by weight for about 3 s-5 s, between the step of forming the oleic acid conversion film and the etching step.

13. An article, comprising:
a substrate made of magnesium alloy;
an oleic acid conversion film formed on the substrate, the oleic acid conversion film being formed by treating the substrate with a chemical conversion treatment solution containing oleic acid as a main film forming agent; and
a ceramic coating comprising refractory metal compound formed on the oleic acid conversion film by physical vapor deposition.

14. The article as claimed in claim 13, wherein oleic acid conversion film is formed by immersing the substrate in the chemical conversion treatment solution, which is maintained at about 35° C., for about 2.5 min; the chemical conversion treatment solution being an aqueous solution containing about 10 ml/L-30 ml/L oleic acid, and ketone compounds, and having a pH value between about 2 and 5.

15. The article as claimed in claim 13, wherein the refractory metal compound is selected from one or more of the group consisting of nitride of titanium, aluminum, chromium, zirconium, or cobalt; carbonitride of titanium, aluminum, chromium, zirconium, or cobalt; and oxynitride of titanium, aluminum, chromium, zirconium, or cobalt.

16. The article as claimed in claim 15, wherein the ceramic coating includes a first layer coated on the oleic acid conversion film and a second layer on the first layer, wherein, the first layer is an aluminum-oxygen compound layer, the second layer is a chromium-oxygen-nitrogen compound layer.
